(19) United States
(12) Patent Application Publication
(10) Pub. No.: US 2014/0239475 A1
(43) Pub. Date: Aug. 28, 2014

(54) PACKAGING SUBSTRATE, SEMICONDUCTOR PACKAGE AND FABRICATION METHODS THEREOF

(71) Applicant: Siliconware Precision Industries Co., Ltd., Taichung (TW)

(72) Inventors: Pang-Chun Lin, Taichung (TW); Yueh-Ying Tsai, Taichung (TW); Yong-Liang Chen, Taichung (TW)

(21) Appl. No.: 13/919,161

(22) Filed: Jun. 17, 2013

(30) Foreign Application Priority Data
Feb. 27, 2013 (TW) 102106856

(51) Int. Cl. H01L 23/31; H01L 23/00

(52) U.S. Cl. CPC H01L 23/3128; H01L 24/96
USPC 257/690; 438/126; 174/251; 29/846

(57) ABSTRACT

A packaging substrate is disclosed, which includes: an encapsulant having opposite first and second surfaces; a plurality of conductive elements embedded in the encapsulant, wherein each of the conductive elements has a first conductive pad exposed from the first surface of the encapsulant and a second conductive pad exposed from the second surface of the encapsulant; and a protection layer formed on the second surface of the encapsulant and the second conductive pads so as to protect the second surface of the encapsulant from being scratched.

### BACKGROUND OF THE INVENTION

1. Field of the Invention

The present invention relates to semiconductor packages, and more particularly, to a semiconductor package and a fabrication method thereof for improving product yield.

2. Description of Related Art

Along with the progress of semiconductor packaging technologies, various semiconductor package types have been developed. A fabrication method of a semiconductor package generally includes: forming a multi-layer circuit structure on a core layer to form a packaging substrate; disposing a chip on the packaging substrate and electrically connecting the chip to the multi-layer structure; and forming an encapsulant on the packaging substrate to encapsulate the chip. However, a certain thickness of the core layer will limit thinning of the package. Therefore, coreless packaging substrates are developed to reduce the size of packages so as to meet the miniaturization requirement of electronic products.

FIGS. 1A to 1D are schematic cross-sectional views showing a conventional fabrication method of a coreless packaging substrate 1′.

Referring to FIG. 1A, a carrier 10 such as a metal plate is provided.

Referring to FIG. 1B, a plurality of first conductive pads 121 are formed on the carrier 10 and then a plurality of second conductive pads 122 are formed on the first conductive pads 121 such that the first conductive pads 121 and the corresponding second conductive pads 122 form a plurality of conductive elements 12.

The first conductive pads 121 can be electrically connected to a semiconductor element such as a chip. The second conductive pads 122 can be used for mounting solder balls. Further, circuits (not shown) can be formed between adjacent first conductive pads 121.

Referring to FIG. 1C, a first encapsulant 11 is formed on the conductive elements 12 and the carrier 10. The first encapsulant 11 has a first surface 11a bonding with the carrier 10 and a second surface 11b opposite to the first surface 11a. The second surface 11b of the first encapsulant 11 is further ground to expose the second conductive pads 122.

Referring to FIG. 1D, a plurality of openings 100 are formed to penetrate the carrier 10 so as to expose the first surface 11a of the first encapsulant 11 and the first conductive pads 121 and the remaining portion of the carrier 10 forms a frame 10′, thereby forming a plurality of packaging substrates 1′.

The frame 10′ is formed on the first surface 11a of the first encapsulant 11 at an outer periphery of the first conductive pads 121. After subsequent packaging processes such as chip disposing and molding processes are performed, the frame 10′ can be removed by cutting, as shown in FIG. 1E.

FIG. 1E shows a conventional eQFN (enhanced quad flat no leads) semiconductor package 1 having the above-described packaging substrate.

Referring to FIG. 1E, a semiconductor element 15 is disposed on a die attach area D on the first surface 11a of the first encapsulant 11 through an adhesive layer 150 and electrically connected to the first conductive pads 121 at an outer periphery of the die attach pad D through a plurality of bonding wires 16.

Then, a second encapsulant 17 is formed on the first surface 11a of the first encapsulant 11 for encapsulating the semiconductor element 15 and the bonding wires 16, and a plurality of solder balls 18 are formed on the second conductive pads 122. Thereafter, a cutting process is performed along the position of the frame so as to form the semiconductor package 1.

However, before the subsequent packaging processes are performed to the packaging substrate 1′, the exposed second surface 11b of the first encapsulant 11 is easily scratched or cracked by an external force or during handling. As such, the packaging substrate 1′ must be discarded and can not be used for the subsequent packaging processes.

Further, since the second conductive pads 122 are exposed from the second surface 11b of the first encapsulant 11, an OSP (organic solderability preservative) process needs to be performed to prevent the second conductive pads 122 from oxidization, thus increasing the fabrication cost.

### SUMMARY OF THE INVENTION

In view of the above-described drawbacks, the present invention provides a packaging substrate, which comprises: an encapsulant having a first surface and a second surface opposite to the first surface; a plurality of conductive elements embedded in the encapsulant, wherein each of the conductive elements has a first conductive pad exposed from the first surface of the encapsulant and a second conductive pad exposed from the second surface of the encapsulant; and a protection layer formed on the second surface of the encapsulant and the second conductive pads.

The present invention further provides a fabrication method of a packaging substrate, which comprises the steps of: forming a plurality of conductive elements on a carrier, wherein each of the conductive elements has a first conductive pad formed on the carrier and a second conductive pad electrically connected to the first conductive pad; forming an encapsulant on the carrier and the conductive elements, wherein the encapsulant has a first surface bonding with the carrier and a second surface opposite to the first surface, and the second conductive pads are exposed from the second surface of the encapsulant; forming a protection layer on the second surface of the encapsulant and the second conductive pads; and removing the carrier so as to expose the first surface of the encapsulant and the first conductive pads.

In the above-described method, the carrier can have a metal layer formed on two opposite sides thereof.

In the above-described packaging substrate and fabrication method thereof, the first conductive pads and the second conductive pads can be made of copper.

In the above-described packaging substrate and fabrication method thereof, the protection layer can be made of metal such as copper.

In the above-described packaging substrate and fabrication method thereof, the carrier can be partially removed to expose the first surface of the encapsulant and the first conductive pads, and the remaining portion of the carrier forms a frame that is located on the first surface of the encapsulant at an outer periphery of the first conductive pads.

The present invention further provides a semiconductor package, which comprises: a first encapsulant having a first surface and a second surface opposite to the first surface; a plurality of conductive elements embedded in the first encapsulant, wherein each of the conductive elements has a first conductive pad exposed from the first surface of the first encapsulant, and a second conductive pad exposed from the second surface of the first encapsulant and having a surface lower than the second surface of the first encapsulant; and a semiconductor element disposed on the first surface of the first encapsulant and electrically connected to the first conductive pads.

The semiconductor package can further comprise a frame located on the first surface of the first encapsulant at an outer periphery of the semiconductor element.

The present invention further provides a fabrication method of a semiconductor package, which comprises the steps of: providing a packaging substrate, which comprises: a first encapsulant having a first surface and a second surface opposite to the first surface; a plurality of conductive elements embedded in the first encapsulant, wherein each of the conductive elements has a first conductive pad exposed from the first surface of the first encapsulant and a second conductive pad exposed from the second surface of the first encapsulant; and a protection layer formed on the second surface of the first encapsulant and the second conductive pads; disposing a semiconductor element on the first surface of the first encapsulant and electrically connecting the semiconductor element and the first conductive pads; and removing the protection layer so as to expose the second surface of the first encapsulant and the second conductive pads.

In the above-described method, the protection layer can be made of metal such as copper. When the protection layer is removed, the second conductive pads can be partially removed so as to have the surfaces of the second conductive pads lower than the second surface of the first encapsulant.

In the above-described semiconductor package and fabrication method thereof, the first conductive pads and the second conductive pads can be made of copper.

In the above-described semiconductor package and fabrication method thereof, the semiconductor element can be electrically connected to the first conductive pads through a plurality of bonding wires.

In the above-described semiconductor package and fabrication method thereof, a second encapsulant can be formed on the first surface of the first encapsulant for encapsulating the semiconductor element.

Further, the packaging substrate can further comprise a frame located on the first surface of the first encapsulant at an outer periphery of the first conductive pads so as for the second encapsulant to be formed therein. After the second encapsulant is formed, the frame can be removed.

In the above-described semiconductor package and fabrication method thereof, a die attach area can be defined on the first surface of the first encapsulant so as for the semiconductor element to be disposed thereon, and a portion of the conductive elements are located at an outer periphery of the die attach area.

In the above-described semiconductor package and fabrication method thereof, after the protection layer is removed, a plurality of solder balls can be formed on the second conductive pads.

According to the present invention, the protection layer is formed on the second surface of the first encapsulant and the second conductive pads so as to prevent the second surface of the first encapsulant from being scratched or cracked.

Further, since the second conductive pads are covered by the protection layer, the invention avoids oxidization of the second conductive pads and eliminates the need to perform an OSP process as in the prior art to thereby reduce the fabrication cost.

### BRIEF DESCRIPTION OF DRAWINGS

FIGS. 1A to 1D are schematic cross-sectional views showing a conventional fabrication method of a packaging substrate;

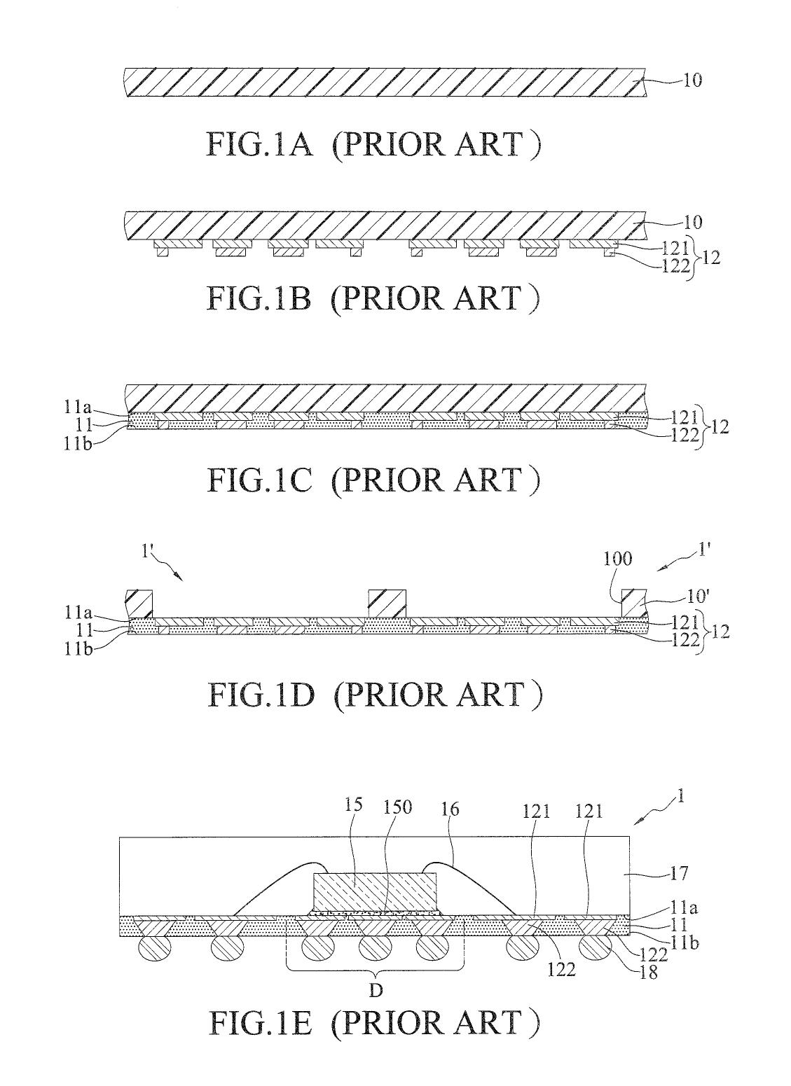

FIG. 1E is a schematic cross-sectional view of a conventional semiconductor package;

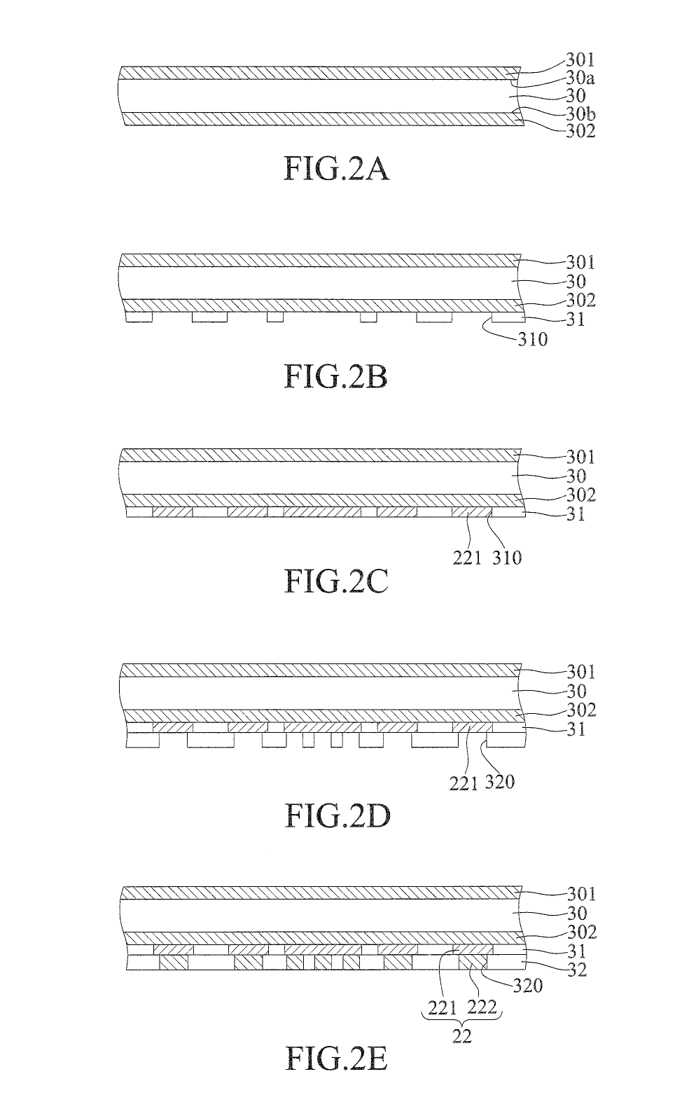

FIGS. 2A to 2I are schematic cross-sectional views showing a fabrication method of a packaging substrate according to the present invention; and

FIGS. 3A to 3D are schematic cross-sectional views showing a fabrication method of a semiconductor package according to the present invention.

### DETAILED DESCRIPTION OF PREFERRED EMBODIMENTS

The following illustrative embodiments are provided to illustrate the disclosure of the present invention, these and other advantages and effects can be apparent to those in the art after reading this specification.

It should be noted that all the drawings are not intended to limit the present invention. Various modifications and variations can be made without departing from the spirit of the present invention. Further, terms such as “lower”, “first”, “second”, “a” etc. are merely for illustrative purposes and should not be construed to limit the scope of the present invention.

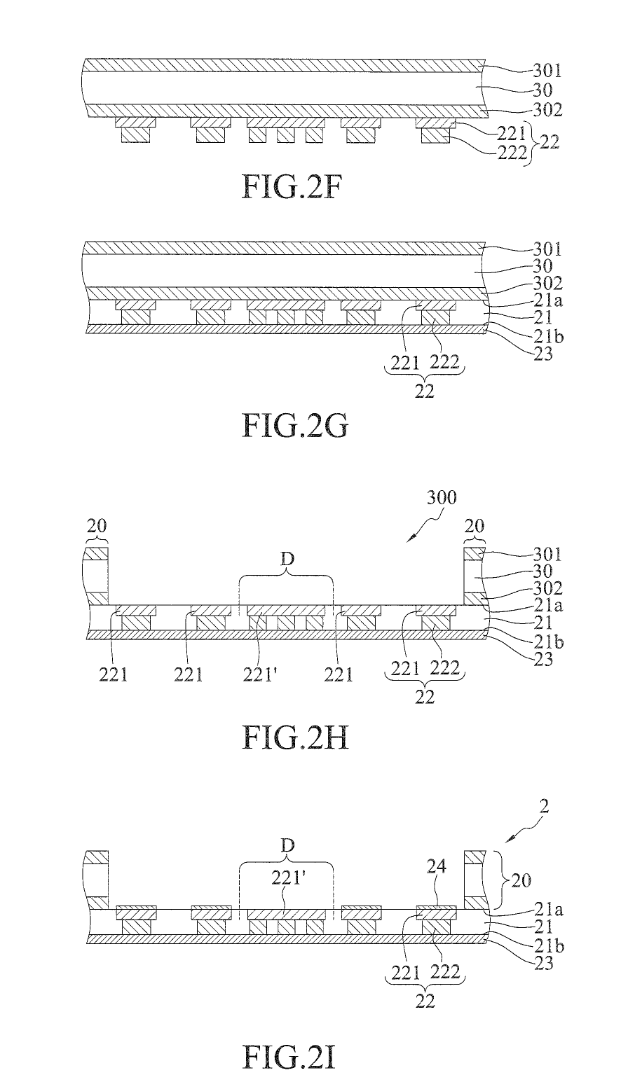

FIGS. 2A to 2I are schematic cross-sectional views showing a fabrication method of a packaging substrate 2 according to the present invention.

Referring to FIG. 2A, a carrier 30 having a first side and second side 30b opposite to the first side 30a is provided. A first metal layer 301 is formed on the first side 30a of the carrier 30 and a second metal layer 302 is formed on the second side 30b of the carrier 30. In other embodiments, the carrier 30 can be a metal plate without the first and second metal layers 301, 302.

Referring to FIG. 2B, a first resist layer 31 is formed on the second metal layer 302 and a plurality of first openings 310 are formed in the first resist layer 31 for exposing portions of the second metal layer 302.

Referring to FIG. 2C, by using the second metal layer 302 as a seed layer, an electroplating process is performed to form a plurality of first conductive pads 221 on the second metal layer 302 in the first openings 310. In the present embodiment, the first conductive pads 221 are made of copper. In other embodiments, the carrier 30 made of a metal plate can directly serve as a current conductive layer for electroplating.

Further, through the design of the pattern of the first openings 310, the first conductive pads 221 and conductive circuits (not shown) connected to the first conductive pads 221 can be formed by the same electroplating process so as to form a patterned circuit layer.

Referring to FIG. 2D, a second resist layer 32 is formed on the first resist layer 31 and the first conductive pads 221, and a plurality of second openings 320 are formed in the second resist layer 32 for exposing portions of the first conductive pads 221.

Referring to FIG. 2E, an electroplating process is performed such that a plurality of second conductive pads 222 are formed in the second openings 320 and electrically connected to the first conductive pads 221. The first conductive pads 221 and the corresponding second conductive pads 222 form a plurality of conductive elements 22. In the present embodiment, the second conductive pads 222 are made of copper.

Further, through the design of the pattern of the second openings 320, the second conductive pads 222 and conductive circuits (not shown) connected to the second conductive pads 222 can be formed by the same electroplating process so as to form a patterned circuit layer.

Referring to FIG. 2F, the first resist layer 31 and the second resist layer 32 are removed to expose the second metal layer 302 and the conductive elements 22.

Referring to FIG. 2G, a pre-molding process is performed to form a first encapsulant 21 on the conductive elements 22 and the carrier 30. The first encapsulant 21 has a first surface 21a, i.e., a top surface, and a second surface 21b, i.e., a bottom surface, opposite to the top surface 21a. The first surface 21a of the first encapsulant 21 bonds with the second metal layer 302 of the carrier 30, and the second conductive pads 222 are exposed from the second surface 21b of the first encapsulant 21.

Then, a protection layer 23 is formed on the second surface 21b of the first encapsulant 21 and the second conductive pads 222. In the present embodiment, the protection layer 23 is made of copper and formed by sputtering or electroless plating.

Referring to FIG. 2H, the carrier 30 and the first and second metal layers 301, 302 are etched to form an opening 300, thereby exposing the first surface 21a of the first encapsulant 21 and the first conductive pads 221.

In the present embodiment, a die attach area D is defined on the first surface 21a of the first encapsulant 21 and a portion of the conductive elements 22 are located at an outer periphery of the die attach area D. The first conductive pad 221′ inside the die attach area D serves as a die attach pad.

The remaining portion of the carrier 30 forms a frame 20, which is located on the first surface 21a of the first encapsulant 21 at an outer periphery of the first conductive pads 221, 221′.

Referring to FIG. 2I, a surface treatment layer 24 is formed on the first conductive pads 221 at the outer periphery of the die attach area D.

In the present embodiment, the surface treatment layer 24 is made of an alloy or multi-layers of Ni, Pd and Au.

In the present invention, the protection layer 23 is formed on the second surface 21b of the first encapsulant 21 to prevent the second surface 21b from being scratched or cracked by an external force or during handling, thereby improving the product yield.

The protection layer 23 is also formed on the second conductive pads 222 to prevent oxidization of the second conductive pads 222. Therefore, the present invention eliminates the need to perform an OSP process as in the conventional art, thereby effectively reducing the fabrication cost.

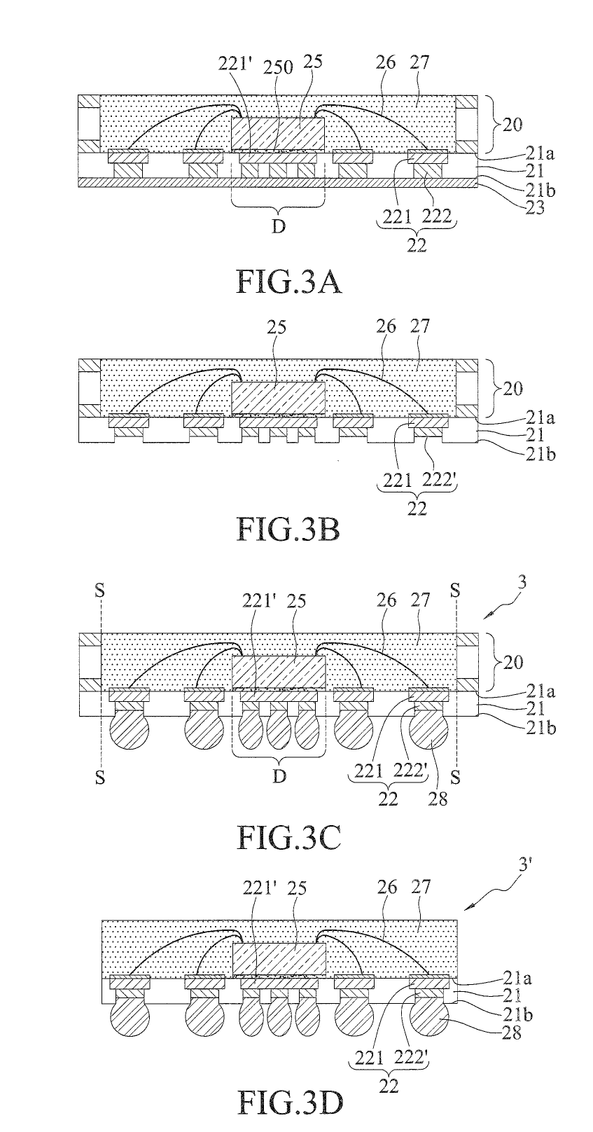

FIGS. 3A to 3D are schematic cross-sectional views showing a fabrication method of a semiconductor package 3, 3′ according to the present invention.

Referring to FIG. 3A, continued from FIG. 2I, at least a semiconductor element 25 is disposed on the die attach area D (i.e., the first conductive pad 221′) on the first surface 21a of the first encapsulant 21 through an adhesive layer 250, and the semiconductor element 25 is electrically connected to the first conductive pads 221 through a plurality of bonding wires 26. In other embodiments, the semiconductor element 25 can be disposed and electrically connected to the first conductive pads 221 in a flip-chip manner.

Then, a second encapsulant 27 is formed on the first surface 21a of the first encapsulant 21 for encapsulating the semiconductor element 25 and the bonding wires 26. In the present embodiment, the second encapsulant 27 is filled in the frame 20.

Referring to FIG. 3B, the protection layer 23 is removed to expose the second surface 21b of the first encapsulant 21 and the second conductive pads 222.

In the present embodiment, when the protection layer 23 is removed by etching, the second conductive pads 222 are also partially removed to form second conductive pads 222′. The surfaces of the second conductive pads 222′ are lower than the second surface 21b of the first encapsulant 21.

Referring to FIG. 3C, a ball mounting process is performed to form a plurality of solder balls 28 on the second conductive pads 222′, thereby forming a semiconductor package 3. The solder balls 28 in the die attach area D are used for heat dissipation.

In another embodiment, referring to FIG. 3D, a cutting process is performed along a cutting path S of FIG. 3C at the position of the frame 20 to form a semiconductor package 3′.

According to the present invention, the protection layer 23 protects the second conductive pads until the ball mounting process. Therefore, the second conductive pads are not easy to oxidize, thus ensuring a strong bonding between the solder balls 28 and the conductive pads 222′ and improving the product yield.

Further, the protection layer 23 can effectively protect the first encapsulant 21 from being scratched or cracked.

The invention further provides a packaging substrate 2, which has: a first encapsulant 21, a plurality of conductive elements 22 embedded in the first encapsulant 21 and a protection layer 23 formed on the first encapsulant 21.

The first encapsulant 21 has a first surface 21a and a second surface 21b opposite to the first surface 21a.

Each of the conductive elements 22 has a first conductive pad 221, 221′ exposed from the first surface 21a of the first encapsulant 21 and a second conductive pad 222 formed on the first conductive pad 221 and exposed from the second surface 21b of the first encapsulant 21.

In the present embodiment, the first conductive pads 221, 221′ and the second conductive pads 222 are made of copper.

The protection layer 23 is formed on the second surface 21b of the first encapsulant 21 and the second conductive pads 222.

In the present embodiment, the protection layer 23 is made of copper.

In an embodiment, the packaging substrate 2 further has a frame 20 located on the first surface 21a of the first encapsulant 21 at an outer periphery of the first conductive pads 221, 221′.

The present invention further provides a semiconductor package 3, 3′, which has: a first encapsulant 21, a plurality of conductive elements 22 embedded in the first encapsulant 21, a semiconductor element 25 disposed on the first encapsulant 21, and a second encapsulant 27 formed on the first encapsulant 21 for encapsulating the semiconductor element 25.

The first encapsulant 21 has a first surface 21a and a second surface 21b opposite to the first surface 21a.

In the present embodiment, a die attach area D is defined on the first surface 21a of the first encapsulant 21 and the semiconductor element 25 is disposed on the die attach area D.

Each of the conductive elements 22 has a first conductive pad 221, 221′ exposed from the first surface 21a of the first encapsulant 21 and a second conductive pad 222′ formed on the first conductive pad 221 and exposed from the second surface 21b of the first encapsulant 21. Further, the second conductive pad 222′ has a surface lower than the second surface 21b of the first encapsulant 21.

In the present embodiment, the first conductive pads 221, 221′ and the second conductive pads 222′ are made of copper. A portion of the conductive elements 22 are located at an outer periphery of the die attach area D, and the first conductive pad 221′ inside the die attach area D serves as a die attach pad. A plurality of solder balls 28 are further formed on the second conductive pads 222′.

The semiconductor element 25 is disposed on the die attach area D on the first surface 21a of the first encapsulant 21 and electrically connected to the first conductive pads 221 at the outer periphery of the die attach area D through a plurality of bonding wires 26.

The second encapsulant 27 is formed on the first surface 21a of the first encapsulant 21 and the first conductive pads 221 (or the surface processing layer 24) for encapsulating the semiconductor element 25 and the bonding wires 26.

In an embodiment, the semiconductor package 3 further has a frame 20 located on the first surface 21a of the first encapsulant 21 at an outer periphery of the semiconductor element 25 (or the second encapsulant 27).

According to the present invention, the packaging substrate has a protection layer formed on the second surface of the first encapsulant thereof so as to prevent the second surface of the first encapsulant from being scratched or cracked.

Further, since the second conductive pads are protected by the protection layer until the ball mounting process begins, the invention avoids oxidization of the second conductive pads and eliminates the need to perform an OSP process as in the prior art to thereby reduce the fabrication cost.

The above-described descriptions of the detailed embodiments are only to illustrate the preferred implementation according to the present invention, and it is not to limit the scope of the present invention. Accordingly, all modifications and variations completed by those with ordinary skill in the art should fall within the scope of present invention defined by the appended claims.

What is claimed is:

1. A packaging substrate, comprising:
an encapsulant having a first surface and a second surface opposite to the first surface;
a plurality of conductive elements embedded in the encapsulant, wherein each of the conductive elements has a first conductive pad exposed from the first surface of the encapsulant and a second conductive pad exposed from the second surface of the encapsulant; and
a protection layer formed on the second surface of the encapsulant and the second conductive pads exposed from the second surfaces of the encapsulant.

2. The substrate of claim 1, wherein the first conductive pads are made of copper.

3. The substrate of claim 1, wherein the second conductive pads are made of copper.

4. The substrate of claim 1, wherein the protection layer is made of metal.

5. The substrate of claim 4, wherein the protection layer is made of copper.

6. The substrate of claim 1, further comprising a frame located on the first surface of the encapsulant at an outer periphery of the first conductive pads.

7. A semiconductor package, comprising:
a first encapsulant having a first surface and a second surface opposite to the first surface;
a plurality of conductive elements embedded in the first encapsulant, wherein each of the conductive elements has a first conductive pad exposed from the first surface of the first encapsulant, and a second conductive pad exposed from the second surface of the first encapsulant and having a surface lower than the second surface of the first encapsulant; and
a semiconductor element disposed on the first surface of the first encapsulant and electrically connected to the first conductive pads.

8. The package of claim 7, wherein a die attach area is defined on the first surface of the first encapsulant, the semiconductor element is disposed thereon, and a portion of the conductive elements are located at an outer periphery of the die attach area.

9. The package of claim 7, wherein the first conductive pads are made of copper.

10. The package of claim 7, wherein the second conductive pads are made of copper.

11. The package of claim 7, further comprising a plurality of solder balls formed on the second conductive pads.

12. The package of claim 7, wherein the semiconductor element is electrically connected to the first conductive pads through a plurality of bonding wires.

13. The package of claim 7, further comprising a second encapsulant formed on the first surface of the first encapsulant for encapsulating the semiconductor element.

14. The package of claim 7, further comprising a frame located on the first surface of the encapsulant at an outer periphery of the semiconductor element

15. A fabrication method of a packaging substrate, comprising the steps of:
forming a plurality of conductive elements on a carrier, wherein each of the conductive elements has a first conductive pad formed on the carrier and a second conductive pad electrically connected to the first conductive pad;
forming an encapsulant on the carrier and the conductive elements, wherein the encapsulant has a first surface bonded with the carrier and a second surface opposite to the first surface, and the second conductive pads are exposed from the second surface of the encapsulant;
forming a protection layer on the second surface of the encapsulant and the second conductive pads; and
removing the carrier to expose the first surface of the encapsulant and the first conductive pads.

16. The method of claim 15, wherein the carrier has a metal layer formed on the first surface and the second surface.

17. The method of claim 15, wherein the first conductive pads are made of copper.

18. The method of claim 15, wherein the second conductive pads are made of copper.

19. The method of claim 15, wherein the protection layer is made of metal.

20. The method of claim 19, wherein the protection layer is made of copper.

21. The method of claim 15, wherein the carrier is partially removed to expose the first surface of the encapsulant and the first conductive pads.

22. A fabrication method of a semiconductor package, comprising the steps of:
providing a packaging substrate, which comprises:
a first encapsulant having a first surface and a second surface opposite to the first surface;
a plurality of conductive elements embedded in the first encapsulant, wherein each of the conductive elements has a first conductive pad exposed from the first surface of the first encapsulant and a second conductive pad exposed from the second surface of the first encapsulant; and
a protection layer formed on the second surface of the first encapsulant and the second conductive pads;
disposing a semiconductor element on the first surface of the first encapsulant and electrically connecting the semiconductor element and the first conductive pads; and
removing the protection layer so as to expose the second surface of the first encapsulant and the second conductive pads.

23. The method of claim 22, wherein the first conductive pads are made of copper.

24. The method of claim 22, wherein the second conductive pads are made of copper.

25. The method of claim 22, wherein the protection layer is made of metal.

26. The method of claim 25, wherein the protection layer is made of copper.

27. The method of claim 22, wherein a die attach area is defined on the first surface of the first encapsulant, the semiconductor element is disposed thereon, and a portion of the conductive elements are located at an outer periphery of the die attach area.

28. The method of claim 22, wherein the semiconductor element is electrically connected to the first conductive pads through a plurality of bonding wires.

29. The method of claim 22, further comprising forming a second encapsulant on the first surface of the first encapsulant for encapsulating the semiconductor element.

30. The method of claim 29, wherein the packaging substrate further comprises a frame located on the first surface of the first encapsulant at an outer periphery of the first conductive pads so as for the second encapsulant to be formed therein.

31. The method of claim 30, after forming the second encapsulant, further comprising removing the frame.

32. The method of claim 22, when removing the protection layer, further comprising partially removing the second conductive pads so as for the surface of the second conductive pads to be lower than the second surface of the first encapsulant.

33. The method of claim 22, after removing the protection layer, further comprising forming a plurality of solder balls on the second conductive pads.

34. The method of claim 32, after removing the protection layer, further comprising forming a plurality of solder balls on the second conductive pads.
